(19) United States
(12) Patent Application Publication
(10) Pub. No.: US 2026/0206366 A1
(43) Pub. Date: Jul. 16, 2026

(54) LED LIGHT SOURCE AND ELECTRONIC DEVICE HAVING THE SAME

(71) Applicant: ADVANCED OPTOELECTRONIC TECHNOLOGY, INC., Hsinchu County (TW)

(72) Inventors: HAO-HSIANG HSIEH, Hsinchu (TW); HSING-TING HUNG, Hsinchu (TW); CHUANG-YU HSIEH, Hsinchu (TW)

(21) Appl. No.: 19/185,552

(22) Filed: Apr. 22, 2025

(30) Foreign Application Priority Data
Jan. 16, 2025 (CN) 202520104046.1

(51) Int. Cl. H10H 20/813; H10H 20/01; H10H 20/825; H10H 20/85; H10H 20/851; H10H 20/855

(52) U.S. Cl. CPC H10H 20/8131; H10H 20/0363; H10H 20/825; H10H 20/8508; H10H 20/8512; H10H 20/855

(57) ABSTRACT

The present disclosure provides an LED light source and an electronic device having the same. The LED light source includes: a light-emitting chip and a lens disposed in the light-emitting chip. An emission spectrum of the light-emitting chip exhibits a dual-peak characteristic. The light-emitting chip is configured to emit blue light and green light. The lens is doped with red phosphor. Wherein the red phosphor is used to mixed with the blue light and the green light emitted by the light-emitting chip to form a white light. In addition, the red phosphor is fluoride-based (KSiF) red phosphor, nitride-based red phosphor, or a mixture thereof. By doping the lens with red phosphor, the dual-peak light-emitting chip can emit light within the desired specific wavelength range.

### FIELD

The subject matter relates to light emitting diode (LED) illumination, and more particularly, to an LED light source with a lens doped with red phosphor, and an electronic device with the LED light source.

### BACKGROUND

An LED light source, which comprises semiconductor compound materials, is usually used in a display panel. The light source of the display panel typically generates white light by mixing red, green, and blue light together.

For example, such light source may add green and red phosphors into a blue LED chip, and the blue LED chip is combined with a transparent and colorless lens. However, the above described LED light source may not be able to emit light within a desired specific wavelength range.

Therefore, there is room for improvement in the art.

### BRIEF DESCRIPTION OF THE DRAWINGS

Implementations of the present technology will now be described, by way of example only, with reference to the attached figures.

FIG. 1 is a diagrammatic view of an LED light source according to an embodiment of the present disclosure.

FIG. 2 is a diagrammatic view of an electronic device according to an embodiment of the present disclosure.

### DETAILED DESCRIPTION

It will be appreciated that for simplicity and clarity of illustration, where appropriate, reference numerals have been repeated among the different FIG.s to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

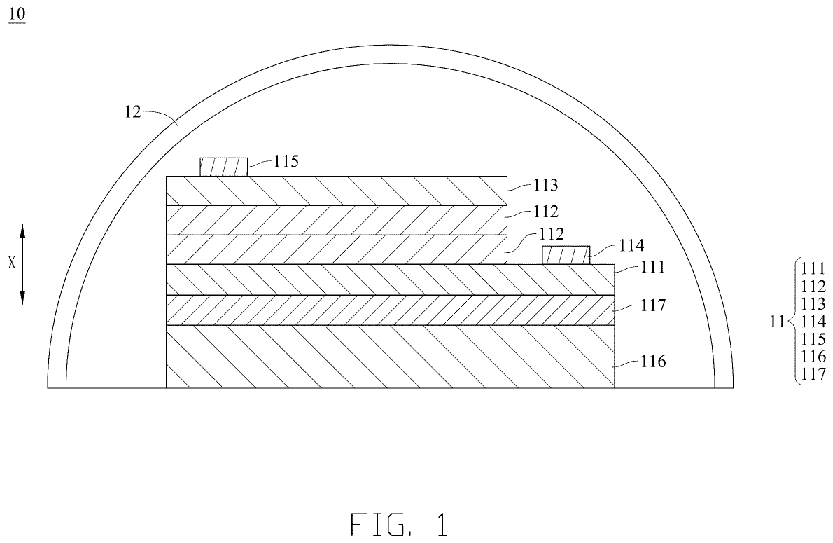

Referring to FIG. 1, an LED light source 10 is provided according to an embodiment of the present disclosure. The LED light source 10 includes a light-emitting chip 11 and a lens 12 disposed on the light-emitting chip 11. An emission spectrum of the light-emitting chip 11 exhibits a dual-peak characteristic. The “dual-peak” refers to an LED emission spectrum with two emission peaks, where the two peaks have different emission wavelengths. The “emission peak” refers to a local maximum at an emission wavelength, where the emission intensity at the peak is at least twice that of adjacent emission wavelengths. Furthermore, the light-emitting chip 11 is an LED chip, a mini-LED chip, or a Micro LED chip. Additionally, the light-emitting chip 11 may emit blue light and green light.

The light-emitting chip 11 is disposed on a substrate (not shown). The light-emitting chip 11 includes a first semiconductor layer 111, two light-emitting layers 112, a second semiconductor layer 113, a first electrode 114, and a second electrode 115. The first semiconductor layer 111, the light-emitting layers 112, and the second semiconductor layer 113 are sequentially stacked along a first direction X. The first direction X is a light-emitting direction of the light-emitting layers 112. That is, the first semiconductor layer 111, the light-emitting layers 112, and the second semiconductor layer 113 are sequentially stacked along the light-emitting direction of the light-emitting layers 112. In an embodiment, the light-emitting layers 112 cover at least a portion of the first semiconductor layer 111. The first electrode 114 is disposed on a portion of the first semiconductor layer 111 not covered by the light-emitting layers 112. The second electrode 115 is disposed on the second semiconductor layer 113. The first electrode 114 and the second electrode 115 are configured to generate signals to control the light-emitting layers 112 to emit blue light and green light, respectively.

In an embodiment, the first semiconductor layer 111 is made of N-type gallium nitride (N-GaN), and the second semiconductor layer 113 is made of P-type gallium nitride (P-GaN). In an embodiment, the first electrode 114 is a positive electrode, and the second electrode 115 is a negative electrode.

In an embodiment, the light-emitting layers 112 are made of the same light-emitting material. For example, the light-emitting layers 112 are made of indium gallium nitride (InGaN). Wherein a mass ratio of indium (In) in the light-emitting layer 112 which is used to emit blue light is less than that in the light-emitting layer 112 which is used to emit green light. In an embodiment, each of the two light-emitting layers 112 is a stacked multiple quantum well (MQW) structure. The “quantum well” refers to a structure that confines the movement of electrons or holes, that is, restricts electrons or holes to a dimension perpendicular to the surface of the light-emitting layer 112. The “multiple quantum well” refers to a structure composed of multiple quantum wells.

The lens 12 is disposed on the light-emitting chip 11 and doped with red phosphor. The red phosphor is fluoride-based (KSiF) red phosphor, nitride-based red phosphor, or a combination thereof. The red phosphor is made of a photoluminescence (PL) material with an emission wavelength ranging from 580 nanometers (nm) to 800 nanometers. The “photoluminescence” refers to a process in which a material absorbs photons or electromagnetic waves and subsequently re-emits photons or electromagnetic waves.

In an embodiment, the blue light and green light, which are emitted by the light-emitting chip 11, pass through the lens 12 doped with red phosphor to form a white light. In an embodiment, the lens 12 is formed by injection molding. In an embodiment, the lens 12 is made of plastic material or silicone with high-transparency. For example, the lens 12 may be made of polycarbonate (PC) or polymethyl methacrylate (PMMA). The lens 12 can be formed by heating material such as polycarbonate, polymethyl methacrylate, or silicone to a molten state and doping the red phosphor into the molten material, then injecting the molten material doped with red phosphor into a mold, and cooling the molten material.

In an embodiment, the light-emitting chip 11 further includes a substrate layer 116. The substrate layer 116 is stacked on a side of the first semiconductor layer 111 opposite to the light-emitting layers 112. In other words, the first semiconductor layer 111, which is made of N-type gallium nitride, is located on a side of the light-emitting layers 112 closer to the substrate layer 116. The second semiconductor layer 113, which is made of P-type gallium nitride, is located on a side of the light-emitting layers 112 farther from the substrate layer 116, thereby ensuring the light-emitting efficiency of the LED light source 10. Furthermore, since the light-emitting layers 112 are made of the same light-emitting material, the lattice constants of the light-emitting layers 112 match each other, and epitaxial defects are minimized, thereby allowing the light-emitting layers 112 to be stacked on the same substrate layer 116. The substrate layer 116 may be made of a material such as sapphire.

In an embodiment, the light-emitting chip 11 further includes a buffer layer 117. The buffer layer 117 is disposed between the substrate layer 116 and the first semiconductor layer 111. The buffer layer 117 is configured to facilitate crystal growth of the first semiconductor layer 111. The buffer layer 117 may be made of undoped gallium nitride (u-GaN).

In an embodiment, since the lens 12 is doped with red phosphor, the blue light and green light emitted by the light-emitting chip 11 pass through the lens 12 doped with red phosphor to form white light. As a result, the light-emitting chip 11 with dual-peak can emit light within the desired specific wavelength range.

In addition, the two light-emitting layers 112 are both made of indium gallium nitride (InGaN) and are stacked along the first direction X. Both of the blue light and green light are emitted from the same light-emitting chip 11, and the two light-emitting layers 112 share the same set of the first electrode 114 and the second electrode 115. Therefore, a manufacturing cost of the LED light source 10 can be reduced compared to the existing light-emitting chips that emit only a single wavelength of light.

In an embodiment, the light-emitting chip 11 is configured to emit blue light and green light. In other embodiments, the light-emitting chip may also be configured to emit light with other wavelengths depending on the application environment.

In an embodiment, the first semiconductor layer 111 may be made of, but not limited to, N-type gallium nitride. The second semiconductor layer 113 may be made of, but not limited to, P-type gallium nitride. In another embodiment, the materials of the first semiconductor layer and the second semiconductor layer may also be interchanged. That is, the first semiconductor layer may also be made of P-type gallium nitride, and the second semiconductor layer may also be made of N-type gallium nitride. That is, the positions of the N-type gallium nitride and P-type gallium nitride may be reversed.

In an embodiment, the first electrode 114 is a positive electrode, and the second electrode 115 is a negative electrode In another embodiment, the polarities of the first electrode and the second electrode may also be interchanged. That is, the first electrode may also be a negative electrode, and the second electrode may also be a positive electrode.

In an embodiment, the red phosphor may be made of, but not limited to, a photoluminescent material with an emission wavelength ranging from 580 nanometers (nm) to 800 nanometers. In another embodiment, photoluminescent materials with other wavelength ranges may also be selected based on application requirements.

In an embodiment, the stacking arrangement of the first semiconductor layer 111, the light-emitting layers 112, the second semiconductor layer 113, the first electrode 114, and the second electrode 115 of the light-emitting chip 11 is for illustration purpose and not limited thereto. In another embodiment, the light-emitting chip may further include a passivation reflection layer, a current blocking layer (CBL), a current spreading layer (not shown), and a gallium nitride (GaN) layer forming an interface between P-type gallium nitride and N-type gallium nitride. The passivation reflection layer may be made of alternating materials with different refractive indices and is configured to protect the chip and prevent short circuits. The current blocking layer may be made of silicon dioxide (SiO₂) and is configured to control the current flow within the light-emitting chip, thereby improving its light-emitting efficiency. The current spreading layer may be made of indium tin oxide (ITO) on the P-type gallium nitride. The current spreading layer has high electrical conductivity and is configured to uniformly spread the current within the light-emitting chip. Wherein, the first semiconductor layer, the two light-emitting layers, the second semiconductor layer, the first electrode, the second electrode, the passivation reflection layer, the current blocking layer, the current spreading layer, and the gallium nitride layer forming the interface between P-type gallium nitride and N-type gallium nitride are stacked, and the stacking order is not limited.

In the LED light source 10 of the above embodiments, since the lens 12 is doped with red phosphor, the blue light and green light emitted by the light-emitting chip 11 pass through the lens 12 doped with red phosphor to form a white light. As a result, the light-emitting chip 11 with the emission spectrum of dual-peak characteristic can emit light within the desired specific wavelength range.

Furthermore, the two light-emitting layers 112 are both made of indium gallium nitride (InGaN) and are stacked along the first direction X. Both of the blue light and green light are emitted from the same light-emitting chip 11, and the two light-emitting layers 112 share the same set of the first electrode and the second electrode. Thus, the manufacturing cost of the LED light source 10 can be reduced compared to the existing light-emitting chips that emit only a single wavelength of light.

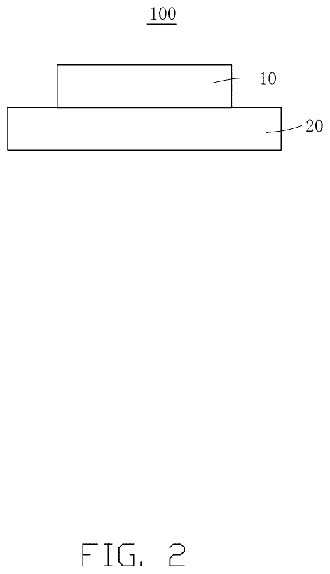

Referring to FIG. 2, an electronic device 100 is provided according to an embodiment of the present disclosure. The electronic device 100 includes a base 20 and the LED light source 10 disposed on the base 20. The LED light source 10 may be applied, for example, in fields of liquid crystal display (LCD) panels or lighting fixtures for plants and animals.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present exemplary embodiments, to the full extent indicated by the plain meaning of the terms in which the appended claims are expressed.

What is claimed is:

1. An LED light source comprising:
a light-emitting chip with an emission spectrum of dual-peak characteristic, and the light-emitting chip configured to emit blue light and green light; and
a lens disposed on the light-emitting chip and doped with red phosphor;
wherein the red phosphor is configured to mix with the blue light and green light emitted by the light-emitting chip to form a white light.

2. The LED light source according to claim 1, wherein the light-emitting chip comprises a first semiconductor layer, two light-emitting layers, a second semiconductor layer, a first electrode, and a second electrode; the first semiconductor layer, the two light-emitting layers, and the second semiconductor layer are sequentially stacked, the first electrode is disposed on the first semiconductor layer, the second electrode is disposed on the second semiconductor layer, the first electrode and the second electrode are configured to generate signals to control the two light-emitting layers to emit the blue light and the green light, respectively.

3. The LED light source according to claim 2, wherein the first semiconductor layer is made of N-type gallium nitride, and the second semiconductor layer is made of P-type gallium nitride.

4. The LED light source according to claim 2, wherein the light-emitting chip further comprises a substrate layer, the substrate layer is stacked on a side of the first semiconductor layer opposite to the two light-emitting layers.

5. The LED light source according to claim 4, wherein the substrate layer is made of sapphire.

6. The LED light source according to claim 2, wherein the light-emitting chip further comprises a buffer layer, the buffer layer is disposed between the substrate layer and the first semiconductor layer.

7. The LED light source according to claim 6, wherein the buffer layer is made of undoped gallium nitride.

8. The LED light source according to claim 1, wherein the red phosphor is made of a photoluminescence material with an emission wavelength ranging from 580 nm to 800 nm.

9. The LED light source according to claim 1, wherein the lens is formed by injection molding, and the lens is made of transparent plastic or silicone.

10. The LED light source according to claim 9, wherein the lens is made of polycarbonate or polymethyl methacrylate.

11. An electronic device comprising:
a base board; and
an LED light source disposed on the base board comprising:
a light-emitting chip with an emission spectrum of dual-peak characteristic, and the light-emitting chip configured to emit blue light and green light; and
a lens disposed on the light-emitting chip and doped with red phosphor;
wherein the red phosphor is configured to mix with the blue light and green light emitted by the light-emitting chip to form a white light.

12. The electronic device according to claim 11, wherein the light-emitting chip comprises a first semiconductor layer, two light-emitting layers, a second semiconductor layer, a first electrode, and a second electrode; the first semiconductor layer, the two light-emitting layers, and the second semiconductor layer are sequentially stacked, the first electrode is disposed on the first semiconductor layer, the second electrode is disposed on the second semiconductor layer, the first electrode and the second electrode are configured to generate signals to control the two light-emitting layers to emit the blue light and the green light, respectively.

13. The electronic device according to claim 12, wherein the first semiconductor layer is made of N-type gallium nitride, and the second semiconductor layer is made of P-type gallium nitride.

14. The electronic device according to claim 12, wherein the light-emitting chip further comprises a substrate layer, the substrate layer is stacked on a side of the first semiconductor layer opposite to the two light-emitting layers.

15. The electronic device according to claim 14, wherein the substrate layer is made of a sapphire.

16. The electronic device according to claim 12, wherein the light-emitting chip further comprises a buffer layer, the buffer layer is disposed between the substrate layer and the first semiconductor layer.

17. The electronic device according to claim 16, wherein the buffer layer is made of undoped gallium nitride.

18. The electronic device according to claim 11, wherein the red phosphor is made of a photoluminescence material with an emission wavelength ranging from 580 nm to 800 nm.

19. The electronic device according to claim 11, wherein the lens is formed by injection molding, and the lens is made of transparent plastic or silicone.

20. The electronic device according to claim 11, wherein the lens is made of polycarbonate or polymethyl methacrylate.
